(19) United States
(12) Patent Application Publication
(10) Pub. No.: US 2004/0144988 A1
(43) Pub. Date: Jul. 29, 2004

(54) Active matric display device including polycrystalline silicon thin film transistor and manufacturing method of the same

(75) Inventor: Yun Ho Jung, Seoul (KR)

Correspondence Address: Brinks Hofer Gilson & Lione, Post Office Box 10395, Chicago, IL, 60610, US

(73) Assignee: LG. PHILIPS LCD CO., LTD.

(21) Appl. No.: 10/742,550

(22) Filed: Dec. 19, 2003

(30) Foreign Application Priority Data
Dec. 31, 2002 (KR) P2002-88482

(51) Int. Cl. H01L 21/00; H01L 33/00; H01L 27/12; H01L 31/0392

(52) U.S. Cl. 257/98; 438/73; 438/82; 438/151; 257/351

(57) ABSTRACT

An active matrix display device includes a plurality of pixels arranged in a matrix form and at least one thin film transistor in each of the plurality of pixels, the at least one thin film transistor including a polycrystalline silicon layer formed by sequential lateral solidification. During fabrication, a mask with slits is disposed over a substrate having an amorphous silicon layer, a first laser beam is applied to a first area of the amorphous silicon layer through the mask, the substrate or laser is moved and the laser beam is applied to a second area of the amorphous silicon layer through the mask. Application of the laser crystallizes the amorphous silicon into a polycrystalline layer. The polycrystalline layers have a substantially identical number of grain boundaries, which in turn have a substantially identical direction and occur at substantially regular intervals.

The present invention claims the benefit of Korean Patent Application No. 2002-088482 filed in Korea on Dec. 31, 2002, which is hereby incorporated by reference for all purposes as if fully set forth herein.

### BACKGROUND OF THE INVENTION

1. Field of the Invention

The present invention relates to an active matrix display device, and more particularly, to an active matrix display device including polycrystalline silicon thin film transistors and a manufacturing method of the same.

2. Discussion of the Related Art

A cathode ray tube is widely used as a display device such as a television and a monitor, and the cathode ray tube has a large size, a heavy weight, and a high driving voltage. Therefore, flat panel displays, which have properties of being thin, low weight and low power consumption, have been proposed. The flat panel displays include a liquid crystal display device, a plasma display panel, a field emission display device, and an electroluminescent display device. The electroluminescent display device uses an electroluminescent phenomenon that emits light when an electric field having a magnitude greater than a fixed value is applied to a fluorescent substance.

Electroluminescent display devices may be categorized into inorganic electroluminescent display devices and organic electroluminescent display devices depending on utilized exciting carrier (transport) materials. The organic electroluminescent display device has attracted considerable attention lately due to its high brightness, low driving voltage of about DC (direct voltage) 5V to about DC 15V, and natural color images from all colors of a visible light spectrum. Additionally, the organic electroluminescent display device has great contrast ratio because of self-luminescence. The organic electroluminescent display device can easily display moving images due to a “full motion” quick response time of about several microseconds, and has a substantially wide viewing angle. The organic electroluminescent display device is stable at a low temperature, and requires low voltage for its driving circuit, which may lead to an easy fabrication process. Thus, a manufacturing process of the organic electroluminescent display device is relatively simple.

In general, an organic electroluminescent display device emits light by injecting an electron from a cathode electrode and a hole from an anode electrode into an emissive layer (zone), combining the electron with the hole to generate an exciton, and permitting the exciton to recombine

Because of its luminous mechanism similar to a light emitting diode, the organic electroluminescent display device may be called an organic light emitting diode (OLED).

Organic electroluminescent display devices are classified into a passive matrix type and an active matrix type according to a respective driving method. Recently, the active matrix organic electroluminescent display (AMOELD) device, which includes a plurality of pixels of a matrix form and where each pixel is independently driven by a thin film transistor, has became widely used as a large size display device.

An active matrix organic electroluminescent display (AMOELD) device according to the related art will be described hereinafter more in detail.

FIG. 1 is an equivalent circuit diagram for a pixel of an AMOELD device according to the related art. In FIG. 1, a gate line 1 and a data line 3 cross each other, thereby defining a pixel P 100, and a power line 5 is parallel to the data line 3. The pixel P 100 includes a switching thin film transistor (TFT) Tsw 6, a driving thin film transistor (TFT) Tdr 7, a storage capacitor Cst 8, and a luminescent diode D 9.

A gate electrode 11 of the switching TFT Tsw 6 is electrically connected to the gate line 1, and a source electrode 12 of the switching TFT Tsw 6 is electrically connected to the data line 3. A drain electrode 13 of the switching TFT Tsw 6 is electrically connected to a gate electrode 14 of the driving TFT Tdr 7. A drain electrode 15 of the driving TFT Tdr 7 is electrically connected to an anode electrode 16 of the luminescent diode D 9, and a source electrode 17 of the driving TFT Tdr 7 is electrically connected to the power line 5. A cathode electrode 18 of the luminescent diode D 9 is grounded. The storage capacitor Cst 8 is electrically connected to the gate electrode 14 and the source electrode 17 of the driving TFT Tdr 7.

When a signal is applied to the gate electrode 11 of the switching TFT Tsw 6 through the gate line 1, the switching TFT Tsw 6 turns on. At this time, a signal from the data line 3 is transmitted to the gate electrode 14 of the driving TFT Tdr 6 through the switching TFT Tsw 6 and is stored in the storage capacitor Cst 8. Then, the driving TFT Tdr 7 is turned on by the signal from the data line 3, and a signal from the power line 5 is transmitted to the luminescent diode D 9 through the driving TFT Tdr 7. Therefore, light is emitted from the luminescent diode D 9. Brightness of the device of FIG. 1 is regulated by controlling current passing through the luminescent diode D 9.

Here, even though the switching TFT Tsw 6 turns off, the driving TFT Tdr maintains an “on” state because of the signal stored in the storage capacitor Cst 9. Accordingly, light is emitted by current continuously passing through the luminescent diode D 9 until the next signal is transmitted to the gate electrode of the driving TFT Tdr 7 through the switching TFT Tsw 6.

In the AMOELD device, polycrystalline silicon is widely used as active layers of the switching TFT Tsw 6 and the driving TFT Tdr 7, and the electrical properties of polycrystalline silicon depend on the grain size, that is, the field effect mobility increases in proportion to the grain size. Accordingly, the formation of single crystalline silicon is important, and recently, a sequential lateral solidification (SLS) method has become of interest. The SLS method takes advantage of the fact that silicon grains grow laterally from the boundary between liquid silicon and solid phase silicon. The SLS method can increase the size of the growing silicon grains by controlling the energy intensity of a laser beam and the irradiation range of the laser beam, as disclosed in PCT international application publication number WO 97/45827 and Korean patent publication number 2001-004129, which are incorporated herein by reference for all purposes as if fully set forth herein.

By the way, a polycrystalline silicon layer formed by the SLS method has grain boundaries at regular intervals. Thus, when the polycrystalline silicon layer is used as an active layer of a thin film transistor, the grain boundaries exist in a channel of the thin film transistor.

FIGS. 2A and 2B are enlarged schematic plan views 20A and 20B showing a switching TFT and a driving TFT according to the related art, respectively.

As shown in FIGS. 2A and 2B, the switching TFT Tsw 28 is connected to a gate line 29 and a data line 30, and includes a semiconductor layer 66, a gate electrode 31, a source electrode 32 and a drain electrode 42. The driving TFT Tdr 60 includes a semiconductor layer 68, a gate electrode 62, a source electrode 52 and a drain electrode 80, which is a part of a pixel electrode. Here, boundaries 66a and 68a are shown in the semiconductor layers 66 and 68, of FIGS. 2A and 2B, respectively. However, the number of boundaries 66a and 68a in the semiconductor layers 66 and 68 are not equal to each other, which may be commonly found when thin film transistors are formed at different places.

Since there are at least one switching TFT and at least one driving TFT at each pixel of the AMOELD device, the AMOELD device having a plurality of pixels includes a plurality of thin film transistors. Thus, if a polycrystalline silicon layer formed by the SLS method is used as semiconductor layers of the plurality of thin film transistors, the number of grain boundaries in each semiconductor layer is not equal due to the positions of the thin film transistors. This is the same as the switching TFT and the driving TFT in one pixel.

In the grain boundary, there is a plurality of defects, and carriers such as electrons or holes may be trapped in the defects. Therefore, if there are grain boundaries in the semiconductor layer, the threshold voltage of the TFT may be increased and reliability in driving the TFT may be lowered.

Theses problems may occur in other active matrix display devices, such as an LCD device, including polycrystalline silicon TFTs.

### SUMMARY OF THE INVENTION

Accordingly, the present invention is directed to an active matrix display device including polycrystalline silicon thin film transistors and a manufacturing method of the same that substantially obviates one or more of problems related to limitations and disadvantages of the related art.

An advantage of the present invention is to provide an active matrix display device including polycrystalline silicon thin film transistors having substantially the same electrical properties.

Another advantage of the present invention is to provide an active matrix display device including polycrystalline silicon thin film transistors and a manufacturing method of the same that produces improved image qualities.

Additional features and advantages of the invention will be set forth in the description which follows, and in part will be apparent from the description, or may be learned by practice of the invention. These and other advantages of the invention will be realized and attained by the structure particularly pointed out in the written description and claims hereof as well as the appended drawings.

To achieve these and other advantages and in accordance with the purpose of the present invention, as embodied and broadly described, an active matrix display device includes a plurality of pixels arranged in a matrix form and at least one thin film transistor in each pixel, the thin film transistor including a polycrystalline silicon layer, wherein every polycrystalline layer in the device has grain boundaries of substantially identical numbers, substantially identical directions and occurring at substantially regular interval.

In another aspect, a method of manufacturing an active matrix display device, wherein the active matrix display device includes a plurality of pixels arranged in a matrix form, includes forming at least a thin film transistor in each pixel such that polycrystalline silicon is used as an active layer of the thin film transistor, wherein forming at least a thin film transistor in each pixel includes steps of forming a polycrystalline silicon layer on a substrate by using a sequential lateral solidification method, wherein the polycrystalline silicon layer has grain boundaries of substantially identical directions and occurring at substantially regular intervals; forming a semiconductor layer by patterning the polycrystalline silicon layer; forming a gate insulating layer and a gate electrode on the semiconductor layer; doping the semiconductor layer using the gate electrode as a mask, thereby forming an active layer, a source region and a drain region; forming an interlayer on the substrate having the active layer, the source region and the drain region thereon, the interlayer including a first contact hole exposing the source region and a second contact hole exposing the drain region; and forming a source electrode and a drain electrode on the interlayer, the source electrode connected to the source region through the first contact hole and the drain electrode connected to the drain region through the second contact hole, wherein every semiconductor layer in the device includes the grain boundaries of substantially identical numbers.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention.

In the drawings:

FIG. 1 is an equivalent circuit diagram for a pixel of an active matrix organic electroluminescent display (AMOELD) device according to the related art;

FIGS. 2A and 2B are enlarged views showing a switching thin film transistor (TFT) and a driving thin film transistor (TFT) of the related art, respectively;

FIGS. 3A and 3B are schematic views showing a process for crystallizing amorphous silicon using a sequential lateral solidification (SLS) method;

FIG. 4 is an equivalent circuit diagram for one pixel of an AMOELD device according to an embodiment of the present invention;

FIG. 5 is a plan view for one pixel of an AMOELD device according to the present invention;

FIGS. 6A and 6B are cross-sectional views along the line VIA-VIA and the line VIB-VIB of FIG. 5, respectively; and

FIGS. 7A and 7B are enlarged views showing a switching TFT and a driving TFT of FIG. 5, respectively.

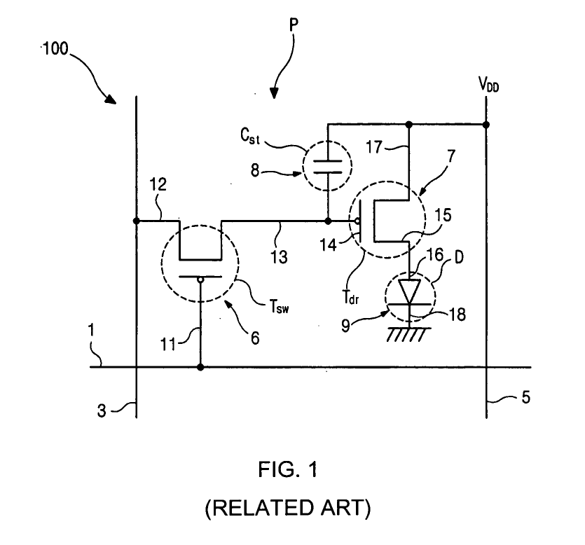

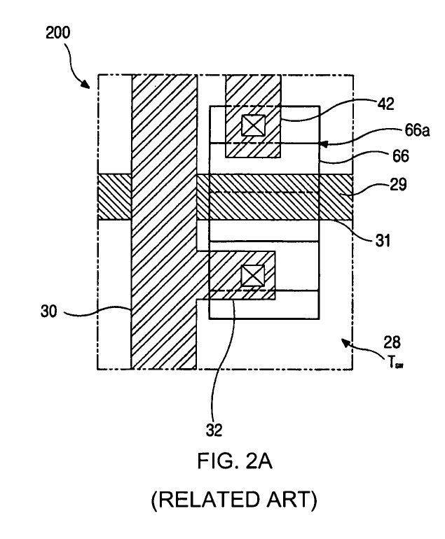

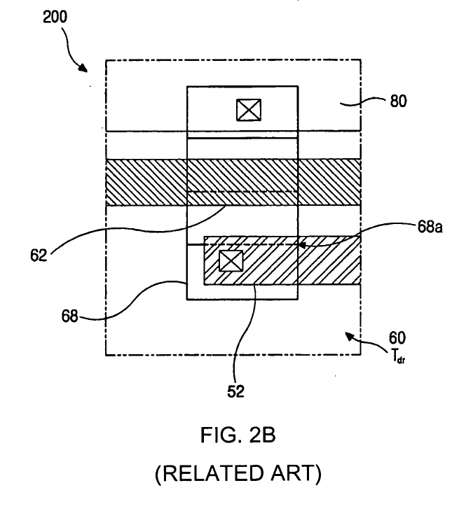

### DETAILED DESCRIPTION OF THE ILLUSTRATED EMBODIMENTS

Reference will now be made in detail to embodiments of the present invention, which are illustrated in the accompanying drawings.

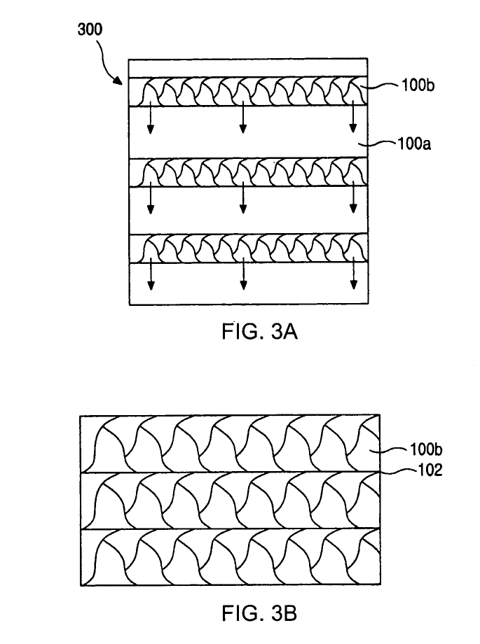

FIGS. 3A and 3B are schematic views showing a process for crystallizing amorphous silicon 300 using the SLS method.

FIG. 3A shows a stage of crystallizing an amorphous silicon 100a by irradiation with a laser beam (not shown) and forming a polycrystalline silicon. The laser beam irradiation on the amorphous silicon layer 100a is performed through a mask (with slits), and thus only a part of the laser beam, which may have a stripe shape, reaches the amorphous silicon layer 100a. The corresponding amorphous silicon layer 100a is melted. After a first laser beam irradiation is performed, in each area exposed to the laser beam, silicon grains grow from an interface between an amorphous silicon area and a melted silicon area. The lateral growth of the silicon grains is vertical with respect to the interface, and the growth length of the silicon grains, which may be affected by various factors, such as an energy density of the laser beam, a processing temperature or status of the amorphous silicon, is within a range of about 1 μm to about 3 μm. Therefore, crystallized regions 100b are formed.

A second laser beam irradiation is performed such that a portion exposed to the second laser beam overlaps a part of the crystallized region 100b. More particularly, the portion exposed to the second laser beam includes not only an amorphous silicon area adjacent to the crystallized region 100b but also one boundary of the crystallized region 100b to prevent other grains from growing independently of the grains in the crystallized region 100b.

The portion exposed to the second laser beam is melted and then crystallized, wherein grains grow continuously from the silicon grains in the crystallized region 100b. The above-mentioned steps are repeatedly performed, and thus, as shown in FIG. 3B, all the amorphous silicon may be changed into crystallized silicon 100b.

Here, a plurality of grain boundaries 102 is regularly shown in the crystallized silicon 100b. The plurality of grain boundaries 102 is perpendicular to the growing direction of the grains and the distance between the grain boundaries 102 corresponds to the interval between laser beam patterns.

The crystallized silicon layer may be used as a semiconductor layer of the AMOELD device. That is, an amorphous silicon layer is deposited on an insulating substrate including a buffer layer and then is crystallized, thereby forming a polycrystalline silicon layer.

The polycrystalline silicon layer is patterned and first and second semiconductor layers are formed. At this time, there are grain boundaries, which may be horizontal or vertical with respect to the surface of the substrate and may have a stripe shape, in the first and second semiconductor layers.

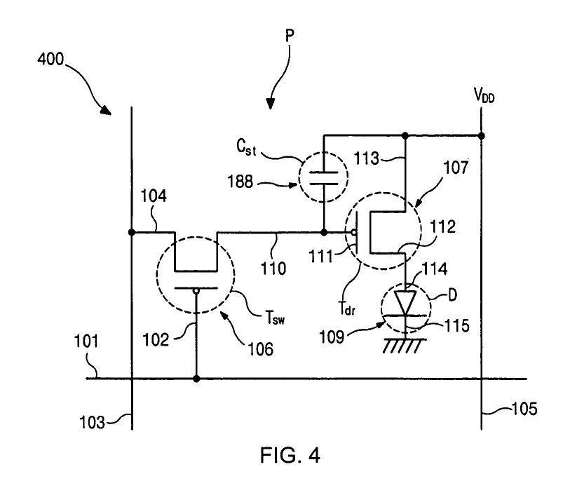

FIG. 4 is an equivalent circuit diagram for one pixel 400 of an AMOELD device according to an embodiment of the present invention. In FIG. 4, a gate line 101 and a data line 103 cross each other, thereby defining a pixel P 400, and a power line 105 is parallel to the data line 103. The pixel P 400 includes a switching thin film transistor (TFT) Tsw 106, a driving thin film transistor (TFT) Tdr 107, a storage capacitor Cst 108, and a luminescent diode D 109.

A gate electrode 102 of the switching Tsw 106 is electrically connected to a gate line 101, and a source electrode 104 of the switching TFT Tsw 106 is electrically connected to a data line 103. A drain electrode 110 of the switching TFT Tsw is electrically connected to a gate electrode 111 of the driving TFT Tdr 107. A drain electrode 112 of the driving TFT Tdr 107 is electrically connected to the luminescent diode D 109, and a source electrode 113 of the driving TFT Tdr 107 is electrically connected to the power line 105. The luminescent diode D 109 includes an anode electrode 114, a cathode electrode 1115, and an organic emitting layer 116 disposed between the anode electrode 114 and the cathode electrode 115. The anode electrode 114 of the luminescent diode D 109 is connected to the drain electrode 112 of the driving TFT Tdr 107 and the cathode electrode 115 of the luminescent diode D 109 is grounded. The storage capacitor Cst 108 is electrically connected to the gate electrode 111 and the source electrode 113 of the driving TFT Tdr 107.

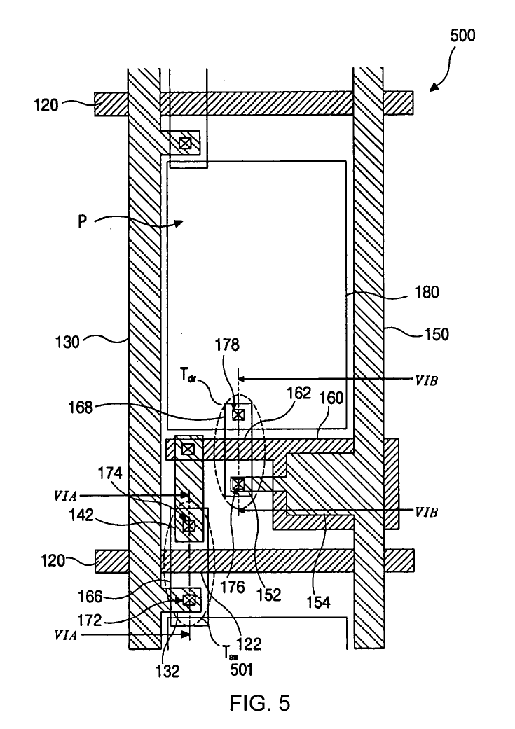

FIG. 5 illustrates a plan view for one pixel 500 of an AMOELD device according to the present invention. In FIG. 5, as stated above, a gate line 120 and a data line 130 cross each other and define a pixel area P. A power line 150 is formed parallel to the data line 130.

A switching TFT Tsw 501 is formed at the crossing of the gate line 120 and the data line 130 and a driving TFT Tdr 502 is formed in the pixel area P. More particularly, a gate electrode 122 of the switching TFT Tsw 501 is connected to the gate line 120 and a source electrode 132 of the switching TFT Tsw 501 is connected to the data line 130. A drain electrode 142 of the switching TFT Tsw 501 is electrically connected to a gate electrode 162 of the driving TFT Tdr 502. In addition, a semiconductor layer 166 of the switching TFT Tsw 501 is connected to the source electrode 132 and the drain electrode 142 through first and second contact holes 172 and 74, respectively. The pixel structure of the AMOELD device may be changed.

As stated above, the gate electrode 162 of the driving TFT Tdr 502 is connected to the drain electrode 142 of the switching TFT Tsw 501 and a first capacitor electrode 160. The source electrode 152 of the driving TFT Tdr 502 is connected to a second capacitor electrode 154 and the power line 150. The second capacitor electrode 154 forms a storage capacitor with the overlapped first capacitor electrode 160. A semiconductor layer 168 of the driving TFT Tdr 502 is connected to the source electrode 152 through a third contact hole 176 and is connected to a pixel electrode 180 through a fourth contact hole 178. Accordingly, a part of the pixel electrode 180 acts as a drain electrode of the driving TFT Tdr 502.

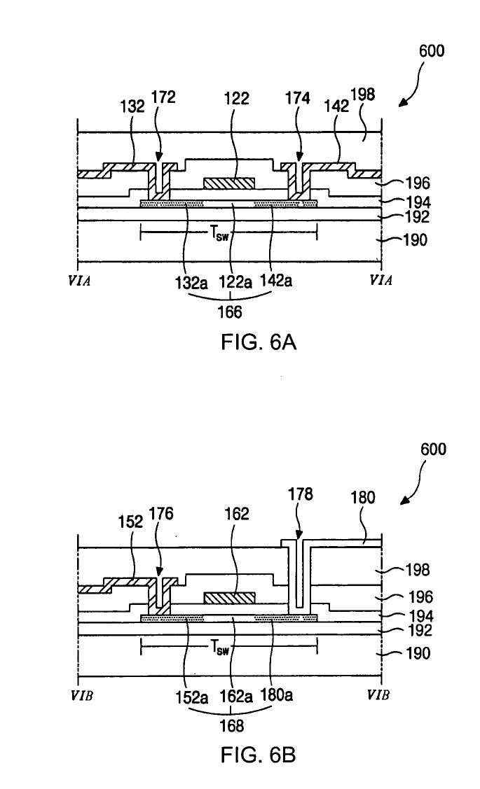

FIGS. 6A and 6B illustrate cross-sections 600 of the pixel 500 along the line VIA-VIA and the line VIB-VIB of FIG. 5, respectively. In FIGS. 6A and 6B, a buffer layer 192 is formed on a transparent insulating substrate 190 to prevent impurities of the substrate 190 from penetrating other layer. A polycrystalline silicon layer is formed on an entire surface of the buffer layer 192 and then is patterned, thereby forming a first semiconductor layer 166, corresponding to a semiconductor layer of the switching TFT Tsw 501, and a second semiconductor layer 168, corresponding to a semiconductor layer of the driving TFT Tdr 502, of island shapes. The first semiconductor layer 166 is divided into a first active layer 122a and first source and drain regions 132a and 142a on either sides of the first active layer 122a, respectively. The second semiconductor layer 168 of FIG. 6B is also divided into a second active layer 162a and second source and drain regions 152a and 180a on either sides of the second active layer 162a, respectively. The first source and drain regions 132a and 142a and the second source and drain regions 152a and 180a are doped.

A gate insulating layer 194 is formed on an entire surface of the buffer layer 192 including the first and second semiconductor layers 166 and 168 thereon. The gate line 120 of FIG. 5, the first gate electrode 122, as a gate electrode of the switching TFT Tsw 501, the second gate electrode 162, as the gate electrode of the driving TFT Tdr 502, and the first capacitor electrode 160 are formed on the gate insulating layer 194 by depositing a first metal layer and patterning it. The first and second gate electrodes 122 and 162 correspond to the first and second semiconductor layers 166 and 168.

An interlayer 196 is formed on an entire surface of the gate insulating layer 194. Next, the interlayer 196 is selectively removed, thereby forming a first contact hole 172 exposing a first source region 132a, a second contact hole 174 exposing a first drain region 142a, and a third contact hole 176 exposing a second source region 152a.

A second metal layer is deposited on the interlayer 196 and then patterned, thereby forming the data line 130 of FIG. 5, the first source and drain electrodes 132 and 142, which are source and drain electrodes of the switching TFT Tsw 501, the power line 150 of FIG. 5, the second capacitor electrode 154 of FIG. 5, and the second source electrode 142, which is a source electrode of the driving TFT Tdr 502. The first source electrode 132 is connected to the first source region 132a through the first contact hole 172, the second source electrode 142 is connected to the first drain region 142a through the second contact hole 174, and the second source electrode 152 is connected to the second source region 152a through the third contact hole 176.

Next, a passivation layer 198 is formed on an entire surface of the second metal layer 196 including the first source and drain electrodes 132 and 142 and the second source electrode 152 thereon. The passivation layer 198 is selectively removed with the interlayer 196 and the gate insulating layer 194, thereby forming a fourth contact hole 178 exposing the second drain region 180a.

A pixel electrode 180 is formed on the passivation layer 198 by depositing a transparent conductive material and then patterning it. The pixel electrode 180 is connected to the second drain region 180a through the fourth contact hole 178. The pixel electrode 180 acts as an anode electrode of a luminescent diode.

Although not shown in the figures, an organic emitting layer may be formed on the pixel electrode 180 and a cathode electrode may be formed on the organic emitting layer. The cathode electrode may be made of an opaque conductive material, and thus the AMOELD device is a bottom emission mode in which light is emitted through a backside of the insulating substrate 190 of the AMOELD device.

As stated above, in the AMOELD device, polycrystalline silicon is used as the semiconductor layers 166 and 168, and the polycrystalline silicon may be formed by the SLS method. At this time, the polycrystalline silicon may have grain boundaries that are spaced apart at regular intervals.

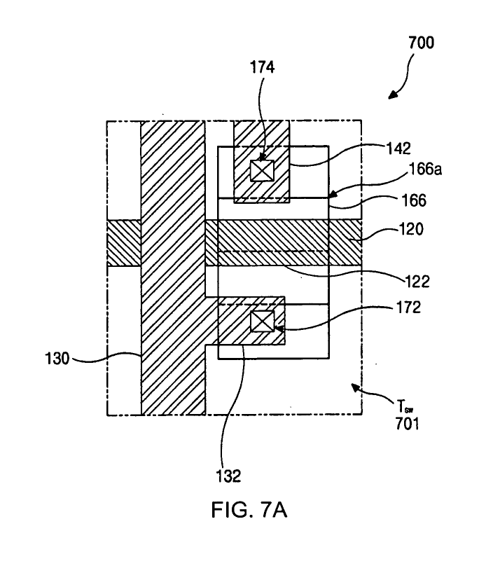

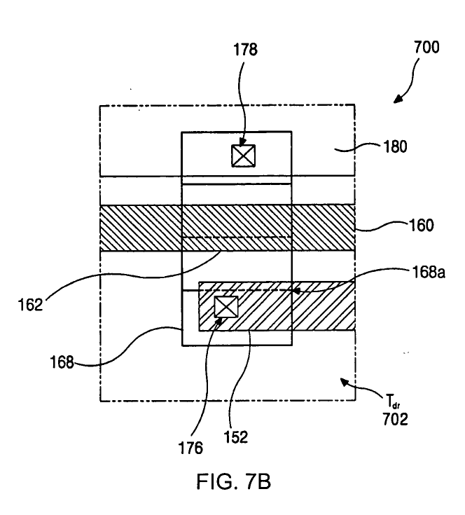

FIGS. 7A and 7B are enlarged views of the pixel 500 showing a switching TFT 701 and a driving TFT 702 of FIG. 5, respectively. In FIGS. 7A and 7B, for a convenience sake of an explanation, the semiconductor layers 166 and 168 are mainly shown and repeated parts will be not mentioned.

As shown in FIGS. 7A and 7B, the semiconductor layers 166 and 168 have boundaries 166a and 168a of the same number and of the same shapes, which can be achieved by controlling the positions of the TFTs. This can be applied to every pixel.

Although only the AMOELD device is described in the embodiment of the present invention, the present invention can be applied to other active matrix display devices, such as a liquid crystal display device, including polycrystalline silicon TFTs.

It will be apparent to those skilled in the art that various modifications and variations can be made in the fabrication and application of the present invention without departing from the spirit or scope of the invention. Thus, it is intended that the present invention cover the modifications and variations of this invention provided they come within the scope of the appended claims and their equivalents.

What is claimed is:

1. An active matrix display device, comprising:
a plurality of pixels arranged in a matrix form; and
at least one thin film transistor in each of the plurality of pixels, the at least one thin film transistor including a polycrystalline silicon layer,
wherein every polycrystalline layer in the device has a substantially identical number of grain boundaries, the grain boundaries having a substantially identical direction and occurring at substantially regular intervals.

2. The device according to claim 1, wherein the at least one thin film transistor includes a gate electrode, a source electrode and a drain electrode.

3. The device according to claim 1, wherein the polycrystalline silicon layer is formed by a sequential lateral solidification method.

4. The device according to claim 1, wherein the active matrix display device is an active matrix organic electroluminescent display device including a switching thin film transistor and a driving thin film transistor in each of the plurality of pixels.

5. The device according to claim 4, further comprising gate and data lines crossing each other to define each of the plurality of pixels.

6. The device according to claim 1, wherein the active matrix display device is an active matrix liquid crystal display device.

7. A method of manufacturing an active matrix display device, wherein the active matrix display device includes a plurality of pixels arranged in a matrix form, comprising:
forming at least one thin film transistor in each of the plurality of pixels such that polycrystalline silicon is used as an active layer of the at least one thin film transistor, including:
forming a polycrystalline silicon layer on a substrate by using a sequential lateral solidification method, wherein the polycrystalline silicon layer has grain boundaries, the grain boundaries having a substantially identical direction and occurring at substantially regular intervals;
forming a semiconductor layer by pattern melting the polycrystalline silicon layer;
forming a gate insulating layer and a gate electrode on the semiconductor layer;
doping the semiconductor layer using the gate electrode, thereby forming
an active layer, a source region and a drain region;
forming an interlayer on the substrate having the active layer, the source region and the drain region thereon, the interlayer including a first contact hole exposing the source region and a second contact hole exposing the drain region; and
forming a source electrode and a drain electrode on the interlayer, the source electrode connected to the source region through the first contact hole and the drain electrode connected to the drain region through the second contact hole,
wherein every semiconductor layer in the device includes a substantially identical number of grain boundaries.

8. The method according to claim 7, wherein each of the plurality of pixels include a switching thin film transistor and a driving thin film transistor.

9. The method according to claim 7, wherein forming the polycrystalline silicon layer includes;
placing a mask over a substrate having an amorphous silicon layer, the mask including slits;
applying a first laser beam to a first area of the amorphous silicon layer through the mask, thereby forming a first crystallization region;
moving the mask relatively to the substrate; and
applying a second laser beam to a second area of the amorphous silicon layer through the mask, thereby forming a second crystallization region, wherein the second area includes a part of the first crystallization region.

10. The method according to claim 7, wherein forming the polycrystalline silicon layer includes;
placing a mask over a substrate having an amorphous silicon layer, the mask including slits along a pattern;
forming a first crystallization region by pattern melting a first area of the amorphous silicon layer;
moving the mask relatively to the substrate; and
forming a second crystallization region by pattern melting a second area of the amorphous silicon layer using the mask, wherein the second area includes a part of the first crystallization region.

11. An apparatus for manufacturing an active matrix display device, wherein the active matrix display device includes a plurality of pixels arranged in a matrix form, the apparatus comprising:
means for forming at least one thin film transistor in each of the plurality of pixels such that polycrystalline silicon is used as an active layer of the at least one thin film transistor, including:
means for forming a polycrystalline silicon layer on a substrate, wherein the polycrystalline silicon layer has grain boundaries, the grain boundaries having a substantially identical direction and occurring at substantially regular intervals;
means for forming a semiconductor layer by patterning the polycrystalline
silicon layer;
means for forming a gate insulating layer and a gate electrode on the semiconductor layer;
means for doping the semiconductor layer using the gate electrode, thereby forming an active layer, a source region and a drain region;
means for forming an interlayer on the substrate having the active layer, the source region and the drain region thereon, the interlayer including a first contact hole exposing the source region and a second contact hole exposing the drain region; and
means for forming a source electrode and a drain electrode on the interlayer, the source electrode connected to the source region through the first contact hole and the drain electrode connected to the drain region through the second contact hole,
wherein every semiconductor layer in the device includes a substantially identical number of grain boundaries.

12. The apparatus according to claim 11, wherein each of the plurality of pixels include a switching thin film transistor and a driving thin film transistor.

13. The apparatus according to claim 11, wherein means for forming the polycrystalline silicon layer includes;
means for placing a mask over a substrate having an amorphous silicon layer, the mask including slits;
means for applying a first laser beam to a first area of the amorphous silicon layer through the mask, thereby forming a first crystallization region;
means for moving the mask relatively to the substrate; and
means for applying a second laser beam to a second area of the amorphous silicon layer through the mask, thereby forming a second crystallization region, wherein the second area includes a part of the first crystallization region.

14. The apparatus according to claim 11, wherein means for forming the polycrystalline silicon layer includes;
means for placing a mask over a substrate having an amorphous silicon layer, the mask including slits with a pattern;
means for pattern melting a first area of the amorphous silicon layer, thereby forming a first crystallization region;
means for moving the mask relatively to the substrate; and
means for pattern melting a second area of the amorphous silicon layer, thereby forming a second crystallization region, wherein the second area includes a part of the first crystallization region.
